(19) United States
(12) Patent Application Publication
(10) Pub. No.: US 2026/0344278 A1
(43) Pub. Date: Oct. 29, 2026

(54) RESISTIVITY-TUNABLE CONDUCTIVE NANOPARTICLE COMPOSITE AND MEMORY DEVICE COMPRISING THE SAME

(71) Applicant: National Tsing Hua University, Hsinchu (TW)

(72) Inventors: Tsun-Hsu Chang, Hsinchu (TW); Wei-Chi Aeneas Hsu, Hsinchu (TW); Bo-Wei Tseng, Hsinchu (TW); Hua-Yan Chen, Hsinchu (TW)

(21) Appl. No.: 19/298,229

(22) Filed: Aug. 13, 2025

(30) Foreign Application Priority Data
Apr. 29, 2025 (TW) 114116204

(51) Int. Cl. H10K 85/20; C08K 3/04; C09D 5/24; C09D 7/61; C09D 163/00; H10K 10/50; H10K 85/10

(52) U.S. Cl. CPC H10K 85/221; C09D 5/24; C09D 7/61; C09D 163/00; H10K 85/10; C08K 3/041; C08K 2201/001; C08K 2201/011; H10K 10/50

(57) ABSTRACT

A resistivity-tunable conductive nanoparticle composite is provided. The composite comprises: conductive nanoparticles with volume percentage concentration of 20-30%; and an insulation matrix, wherein the conductive nanoparticles are uniformly dispersed in the insulation matrix, wherein resistivity of the conductive nanoparticle is 10⁻⁸-10⁻⁴ Ω·cm, wherein resistivity of the insulation matrix is 10⁸-10¹⁸ Ω·cm, and initial resistivity of the composite is 10⁻⁴-10⁸ Ω·cm.

### CROSS-REFERENCE TO RELATED APPLICATION

This application claims the priority of Taiwanese patent application No. 114116204, filed on Apr. 29, 2025, which is incorporated herewith by reference.

### BACKGROUND OF THE INVENTION

### 1. Field of the Invention

The present invention relates generally to a resistivity-tunable composite, and more particularly, to a resistivity-tunable conductive nanoparticle composite and a memory device comprising the same.

### 2. The Prior Arts

Traditional memory device materials are mostly used in mature semiconductor device manufacturing processes, such as the related processes of complementary metal-oxide semiconductor (CMOS) and metal-oxide semiconductor field effect transistor (MOSFET). Complementary metal-oxide semiconductor is an integrated circuit (IC) design process that can produce the basic components of NMOS (n-type MOSFET) and PMOS (p-type MOSFET) on a silicon wafer template. Since NMOS and PMOS are complementary in physical properties, they are called CMOS. This general process can be used to produce static random access memory, microcontrollers, microprocessors and other digital logic circuit systems for computer appliances. In addition, being through some different processing, it can achieve more special technical characteristics, allowing it to be used in optical instruments.

The aforementioned semiconductor manufacturing process usually involves complicated manufacturing procedures, such as epitaxy, semiconductor doping, coating, sputtering, photolithography, etc. In addition to the huge and complicated procedures, the process time and cost are also considerable.

However, in some application fields, such delicate semiconductor memory devices are not required, such that memory materials with lower cost and faster manufacturing are desired.

Therefore, the present invention is provided after observing the above-mentioned deficiency.

### SUMMARY OF THE INVENTION

In order to effectively solve the aforementioned problems, according to an aspect of the present invention, the present application provides a resistivity-tunable conductive nanoparticle composite, comprising: conductive nanoparticles with volume percentage concentration of 20-30%; and an insulation matrix, wherein, the conductive nanoparticles are uniformly dispersed in the insulation matrix, wherein resistivity of the conductive nanoparticle is 10⁻⁸-10⁻⁴ Ω·cm, wherein resistivity of the insulation matrix is 10⁸-10¹⁸ Ω·cm, and wherein initial resistivity of the composite is 10⁻⁴-10⁸ Ω·cm.

According to the embodiments of the present invention, preferably, resistivity of the composite is lower than the initial resistivity thereof after the composite is submitted to an electric field for an applying time, a power relationship between the resistivity of the composite and the applying time is ρ(t)=kt\hat{ }(−α), ρ is the resistivity, t is the applying time, k is a fitting constant, and α is a critical exponent, the critical exponent is 0.1-0.4, and the resistivity remains the same after the electric field is turned off.

According to the embodiments of the present invention, preferably, after the composite is submitted to an electric field for a predetermined applying time, resistivity thereof is lower than 0.1 times the initial resistivity thereof, and the resistivity remains the same after the electric field is turned off.

According to the embodiments of the present invention, preferably, after the composite is submitted to an electric field for a predetermined applying time, resistivity thereof is lower than 0.01 times the initial resistivity thereof, and the resistivity remains the same after the electric field is turned off.

According to the embodiments of the present invention, preferably, intensity of the electric field is 9-18 V·cm⁻¹, and the predetermined applying time is less than 1000 ms.

According to the embodiments of the present invention, preferably, the resistivity of the composite returns to the initial resistivity thereof after the composite is heated at a predetermined temperature for a predetermined heating time.

According to the embodiments of the present invention, preferably, the predetermined temperature is 80-100 °C, and the predetermined heating time is 30-120 s.

According to the embodiments of the present invention, preferably, the conductive nanoparticles are metal nanoparticles, and the insulation matrix is epoxy, acrylate, silastic, or a combination thereof.

According to the embodiments of the present invention, preferably, the conductive nanoparticles are carbon nanotubes, and the insulation matrix is epoxy, acrylate, silastic, or a combination thereof.

In order to effectively solve the aforementioned problems, according to another aspect of the present invention, the present application provides A memory device, comprising: a substrate; and a composite layer disposed on the substrate, wherein, the composite layer including the composite according to the preceding paragraphs, and wherein, the composite layer is divided into a plurality of blocks as memory units and an electrode is disposed on two opposite sides of each of the plurality of blocks.

According to the embodiments of the present invention, preferably, the electrodes of each of the plurality of blocks are disposed on the two opposite sides of an upper surface thereof, and adjacent two blocks share one electrode.

According to the embodiments of the present invention, preferably, the electrodes of each of the plurality of blocks are disposed on an upper surface and a lower surface thereof as an upper electrode and a lower electrode, and the lower electrodes of the plurality of block are connected as a common electrode.

The present invention provides a conductive nanoparticle composite, which has a relatively simple manufacturing process and exhibits semiconductor-like properties, and can realize the function of storing information in a memory device without using the current generally complex and expensive semiconductor manufacturing process.

In order to make those skilled in the art understand the purpose, features and effects of the present invention, the present invention is described in detail below by the following specific embodiments, and in conjunction with the attached drawings.

### BRIEF DESCRIPTION OF THE DRAWINGS

FIG. 1 is a data graph illustrating the percolation threshold of the conductive nanoparticle composite according to an exemplary embodiment of the present invention.

FIG. 2 is a flow chart illustrating the method for manufacturing the conductive nanoparticle composite according to an exemplary embodiment of the present invention.

FIG. 3 is a perspective view illustrating the memory device according to an exemplary embodiment of the present invention.

### DETAILED DESCRIPTION OF THE PREFERRED EMBODIMENT

Generally speaking, conductors, semiconductors, and insulators can be distinguished based on their resistivity, wherein the resistivity of conductors is 10⁻⁸-10⁻⁴ Ω·cm; the resistivity of semiconductors is 10⁻⁴-10⁸ Ω·cm; and the resistivity of insulators is 10⁸-10¹⁸ Ω·cm. Semiconductor materials, such as silicon and germanium, can have their conductive properties adjusted and controlled by temperature, electric field, doping, etc., and can therefore be widely used in micro-switch components, memory components, etc.

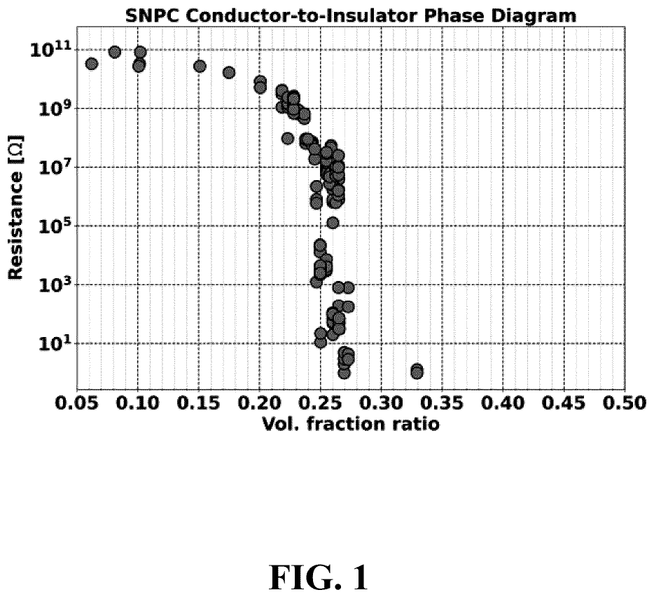

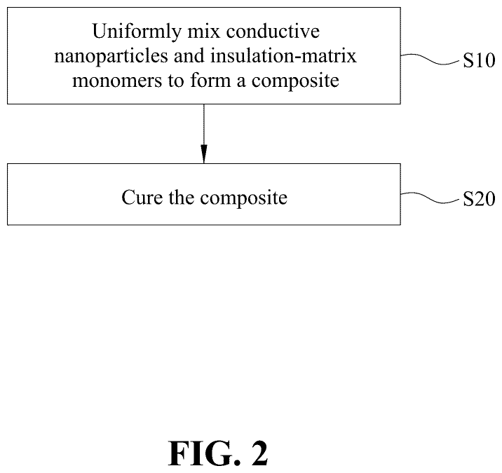

Refer to FIGS. 1-2 below. FIG. 1 is a data graph illustrating the percolation threshold of the conductive nanoparticle composite according to an exemplary embodiment of the present invention; and FIG. 2 is a flow chart illustrating the method for manufacturing the conductive nanoparticle composite according to an exemplary embodiment of the present invention.

In the present invention, conductive nanoparticles and an insulation matrix material are uniformly mixed into a composite having semiconductor-like properties (step S10). In detail, referring to FIG. 1, by controlling the volume fraction of the conductive nanoparticles in the composite to be near the percolation threshold (e.g., about 23-27%), a conductive nanoparticle composite having a resistivity of 10⁻⁴-10⁸ Ω·cm can be obtained, wherein the resistance value in FIG. 1 is obtained by measuring the composite of the present invention with electrodes having a spacing of 1 cm. That is, the conductive nanoparticle composite of the present invention has resistivity characteristics similar to those of semiconductor materials.

The volume fraction of the conductive nanoparticles in the conductive nanoparticle composite of the invention may be 20-30%; preferably, the volume fraction of the conductive nanoparticles may be 23-27%; and preferably, the volume fraction of the conductive nanoparticles may be 24-26%.

According to an embodiment of the present invention, the conductive nanoparticles may be metal nanoparticles, such as silver, copper, gold, or aluminum nanoparticles, but the present invention is not limited thereto. In addition, the conductive nanoparticles may also be carbon nanotubes.

According to an embodiment of the present invention, the insulation matrix may be epoxy resin, acrylate, silastic, or a combination thereof. The composite formed by uniformly mixing the conductive nanoparticles and the insulation matrix material of the present invention may be subjected to a curing process (step S20), wherein the uniform mixing process (step S10) may include a corresponding curing agent or hardening agent in addition to the conductive nanoparticles and the insulation matrix material. The curing process (step S20) may be heating curing, ultraviolet light curing, or a combination thereof, but the present invention is not limited thereto.

According to an embodiment of the present invention, the resistivity of the conductive nanoparticle composite of the present invention can be controlled by applying an external electric field. The external electric field may be generated by a direct current voltage or a single rectangular pulse voltage, but the present invention is not limited thereto. The resistivity of the conductive nanoparticle composite of the present invention equals initial resistivity just after being manufactured, and after an electric field is applied thereto for a certain period of time, the resistivity thereof is smaller than the initial resistivity. Preferably, after the conductive nanoparticle composite of the present invention is applied with an electric field for a predetermined applying time, its resistivity after the application of the electric field will be less than 0.1 times its initial resistivity; preferably, after the conductive nanoparticle composite of the present invention is applied with an electric field for a predetermined applying time, its resistivity after the application of the electric field will be less than 0.01 times its initial resistivity; and preferably, after the conductive nanoparticle composite of the present invention is applied with an electric field for a predetermined applying time, its resistivity after the application of the electric field will be less than 0.001 times its initial resistivity. In addition, the electric field intensity may be 9-18 V·cm⁻¹; and preferably, the electric field intensity may be 12-15 V·cm⁻¹. In addition, the predetermined applying time may be less than 1000 ms; preferably, the predetermined applying time may be less than 100 ms; and preferably, the predetermined applying time may be less than 10 ms; for example, the predetermined applying time may be 10-1000 ms. The predetermined applying time of the external electric field may depend on the electric field intensity and the initial resistivity of the conductive nanoparticle composite. For example, if the applied electric field is larger, the predetermined applying time is shorter; and if the initial resistivity thereof is larger, the predetermined applying time is shorter.

According to an embodiment of the present invention, the power relationship between the resistivity of the conductive nanoparticle composite of the present invention and the electric field applying time can be ρ(t)=kt\hat{ }(−α), wherein ρ is the resistivity, which may depend on the electric field intensity and the initial resistivity of the conductive nanoparticle composite; t is the electric field applying time, in units of ms; k is the fitting constant; α is the critical exponent; and the resistivity after the electric field is applied remains unchanged after the electric field is removed. The above power relationship between the resistivity ρ and the electric field applying time holds good in the range of 10¹ ms<t<10⁵ ms. The critical exponent may be 0.1-0.4; and preferably, the critical exponent may be 0.3-0.4. If the external electric field is applied in stages, the electric field applying time t can be the cumulative electric field applying time. The degree of resistivity decrease can be controlled more accurately by applying the electric field in stages and measuring the resistivity. For example, if the electric field is applied three times, each for 10 ms, then t=30 ms.

According to an embodiment of the present invention, after the resistivity of the conductive nanoparticle composite of the present invention is reduced by the action of applying an electric field, the resistivity can be restored to the initial resistivity by heating at a predetermined temperature for a predetermined heating time. The predetermined temperature may be 80-100 °C; and preferably, the predetermined temperature may be greater than 80-90 °C. In addition, the predetermined heating time may be 30 to 120 s; preferably, the predetermined heating time may be 30 to 60 s; and preferably, the predetermined heating time may be 30 to 45 s. Within a reasonable range, the larger the volume or thickness of the conductive nanoparticle composite of the present invention is, the longer the required predetermined heating time will be.

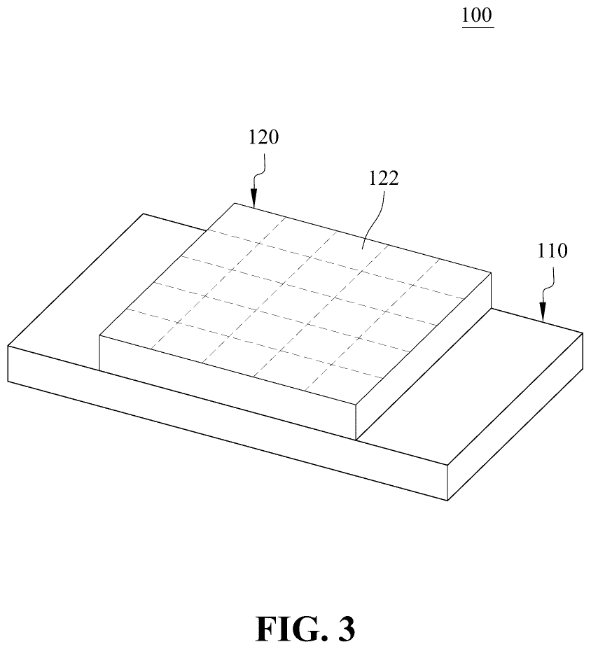

Please refer to FIG. 3. FIG. 3 is a perspective view illustrating the memory device according to an exemplary embodiment of the present invention.

The following will further describe in detail the manufacturing process of the conductive nanoparticle composite and the related memory device of the present invention.

First, silver nanoparticles (US Research Nanomaterials, Inc.), epoxy resin monomers (Hong-Ming Technology Co., Ltd.: D01-DTE-206LA), and corresponding hardener (Hong-Ming Technology Co., Ltd.: D01-DTE-206LB) are uniformly mixed into a viscous composite (step S10), wherein the volume percentage concentration of the silver nanoparticles is 25±1% of the composite, the purity of the silver nanoparticles is 99.99%, the density of the silver nanoparticles is 10.5 g/cm³, and the particle size of the silver nanoparticles is 20 nm, and the weight ratio of the epoxy resin monomers to the corresponding hardener is 3:1. Then, the mixed viscous composite is coated on the substrate 110 (e.g., glass substrate) of the memory device 100, soft-baked at 80 °C for 75 min and then hard-baked at 100 °C for 10 min (step S20) to form a cured composite layer 120 with a thickness of 2 mm. The composite layer 120 is divided into a plurality of blocks 122 of 1×1 cm² as memory units. For example, as shown in FIG. 3, the composite layer 120 is divided into 25 equal blocks 122 of a surface area of 1×1 cm². Silver electrodes are then plated on two opposite sides of each block 122 for applying an electric field to the block 122 and measuring resistance. Two adjacent blocks 122 may share one electrode. Such a composite layer 120 can be used to locally tune the resistivity thereof. For example, a voltage of 12 V is selectively applied to certain blocks 122 (writing) for 100 ms, and the blocks 122 to which the voltage is not applied have a high resistivity (initial resistivity), while the blocks 122 to which the voltage is applied have a low resistivity. For example, the initial resistance of each 1 ×1 cm² block 122 of the composite layer 120 is about 10⁵Ω, and the resistance of a certain block 122 drops to about 10³Ω after voltage is applied, which is about 2 orders of magnitude different from the initial resistance. In this way, the block 122 with high resistivity is regarded as “0” and the block 122 with low resistivity is regarded as “1”, so that the storage of binary-digit (bit)-based data can be achieved. Alternatively, information can be stored in the form of a two-dimensional pattern for encoding and decoding operations. Finally, the composite layer 120 with written data can be erased by heated at 80 °C for 45 s. The above numerical values and orders of magnitude are merely examples, and the present invention is not limited thereto. Actual implementation conditions may be arbitrarily adjusted to produce different result values. For example, the thickness of the composite layer 120 may be 1-10 mm.

According to another embodiment of the present invention, a conductive layer may be formed on the substrate 110 of the memory device 100 as a common lower electrode of the blocks 122 of the composite layer 120, and then respective upper electrode may be formed on each block 122, thereby simplifying the wiring of the memory device 100.

The above is to illustrate the implementation of the present invention by means of specific examples. Those skilled in the art can easily understand other advantages and effects of the present invention from the content disclosed in this specification.

The above are only preferred embodiments of the present invention, and are not intended to limit the scope of the present invention; all other equivalent changes or modifications that do not depart from the spirit disclosed by the present invention should be included in the following within the scope of the patent.

What is claimed is:

1. A resistivity-tunable conductive nanoparticle composite, comprising
conductive nanoparticles with volume percentage concentration of 20-30%; and
an insulation matrix,
wherein, the conductive nanoparticles are uniformly dispersed in the insulation matrix,
wherein resistivity of the conductive nanoparticle is 10⁻⁸-10⁻⁴ Ω·cm,
wherein resistivity of the insulation matrix is 10⁸-10¹⁸ Ω·cm, and
wherein initial resistivity of the composite is 10⁻⁴-10⁸ Ω·cm.

2. The composite according to claim 1, wherein
resistivity of the composite is lower than the initial resistivity thereof after the composite is submitted to an electric field for an applying time,
a power relationship between the resistivity of the composite and the applying time is ρ(t)=kt\hat{ }(−α),
ρ is the resistivity, t is the applying time, k is a fitting constant, and α is a critical exponent,
the critical exponent is 0.1-0.4, and
the resistivity remains the same after the electric field is turned off.

3. The composite according to claim 1, wherein
after the composite is submitted to an electric field for a predetermined applying time, resistivity thereof is lower than 0.1 times the initial resistivity thereof, and
the resistivity remains the same after the electric field is turned off.

4. The composite according to claim 1, wherein
after the composite is submitted to an electric field for a predetermined applying time, resistivity thereof is lower than 0.01 times the initial resistivity thereof, and
the resistivity remains the same after the electric field is turned off.

5. The composite according to claim 3, wherein
intensity of the electric field is 9-18 V·cm⁻¹, and
the predetermined applying time is less than 1000 ms.

6. The composite according to claim 2, wherein the resistivity of the composite returns to the initial resistivity thereof after the composite is heated at a predetermined temperature for a predetermined heating time.

7. The composite according to claim 6, wherein
the predetermined temperature is 80-100 °C, and
the predetermined heating time is 30-120 s.

8. The composite according to claim 1, wherein
the conductive nanoparticles are metal nanoparticles, and
the insulation matrix is epoxy, acrylate, silastic, or a combination thereof.

9. The composite according to claim 1, wherein
the conductive nanoparticles are carbon nanotubes, and
the insulation matrix is epoxy, acrylate, silastic, or a combination thereof.

10. A memory device, comprising:
a substrate; and
a composite layer disposed on the substrate,
wherein, the composite layer including the composite according to claim 1, and
wherein, the composite layer is divided into a plurality of blocks as memory units and an electrode is disposed on two opposite sides of each of the plurality of blocks.

11. The memory device according to claim 10, wherein
the electrodes of each of the plurality of blocks are disposed on the two opposite sides of an upper surface thereof, and
adjacent two blocks share one electrode.

12. The memory device according to claim 10, wherein
the electrodes of each of the plurality of blocks are disposed on an upper surface and a lower surface thereof as an upper electrode and a lower electrode, and
the lower electrodes of the plurality of block are connected as a common electrode.
